(19) United States
(12) Patent Application Publication
(10) Pub. No.: US 2026/0308749 A1
(43) Pub. Date: Oct. 8, 2026

(54) DEPOSITION APPARATUS, THIN-FILM DEPOSITION METHOD USING THE SAME, AND ELECTRONIC APPARATUS MANUFACTURED USING THE SAME

(71) Applicant: Samsung Display Co., LTD., Yongin-si (KR)

(72) Inventors: JEONGWON HAN, Yongin-si (KR); JAEWON SHIM, Yongin-si (KR); SUKWON JUNG, Yongin-si (KR)

(21) Appl. No.: 19/407,354

(22) Filed: Dec. 3, 2025

(30) Foreign Application Priority Data
Apr. 3, 2025 (KR) 10-2025-0043733

(51) Int. Cl. C23C 14/50; C23C 14/04; C23C 14/24; C23C 14/54; H10K 59/12; H10K 71/16

(52) U.S. Cl. CPC C23C 14/505; C23C 14/042; C23C 14/24; C23C 14/54; H10K 59/1201; H10K 71/166

(57) ABSTRACT

A deposition apparatus includes a first support part, a mask frame disposed on the first support part and defining a frame opening, a mask disposed on an upper surface of the mask frame and defining a mask opening, an electrostatic chuck disposed on the mask with a substrate disposed thereunder, a second support part movable in a first direction and disposed on the first support part with a first support opening defined in an upper surface and a second support opening defined in a lower surface, a (1-1)-th stage disposed in the first support opening and rotating about a rotation axis, a (1-2)-th stage disposed on the (1-1)-th stage and defining first openings, a (2-1)-th stage disposed in the second support opening and rotating about the rotation axis, a (2-2)-th stage disposed on the (2-1)-th stage and defining second openings, and sensors respectively disposed in the first and second openings.

This application claims priority to Korean Patent Application No. 10-2025-0043733, filed on Apr. 3, 2025, and all the benefits accruing therefrom under 35 U.S.C. §119, the content of which in its entirety is herein incorporated by reference.

### BACKGROUND

### 1. Field

The disclosure herein relates to a deposition apparatus, a thin-film deposition method using the same, and an electronic apparatus.

### 2. Description of the Related Art

Display devices output an image or video through a display region so as to provide a variety of visual information to a user. An organic light-emitting display device among the display devices has advantages not only of a relatively wide viewing angle and excellent contrast, but also of a relatively fast response speed. A display region of the organic light-emitting display device may be composed of a plurality of pixels, and the plurality of pixels may form the display region through a deposition process of a deposition material.

### SUMMARY

The disclosure provides a deposition apparatus, which may prevent flatness of an electrostatic chuck and a substrate and sagging of a mask, a thin-film deposition method using the same, and an electronic apparatus.

An embodiment of the inventive concept provides a deposition apparatus including a first support part, a mask frame which is disposed on the first support part, and in which a frame opening is defined, a mask which is disposed on an upper surface of the mask frame, and in which a mask opening is defined, an electrostatic chuck which is disposed on the mask, and under which a substrate is disposed, a second support part, which is disposed on the first support part, with a first support opening defined in an upper surface and a second support opening defined in a lower surface, a (1-1)-th stage disposed in the first support opening, and configured to rotate about a rotation axis perpendicular to a plane, a (1-2)-th stage which is disposed on the (1-1)-th stage, and in which a plurality of first openings are defined, a (2-1)-th stage disposed in the second support opening, and configured to rotate about the rotation axis perpendicular to the plane, a (2-2)-th stage which is disposed on the (2-1)-th stage, and in which a plurality of second openings are defined, and a plurality of sensors respectively disposed in the plurality of first openings and the plurality of second openings, where the second support part is movable in a first direction.

In an embodiment, in the plan view, the (1-2)-th stage and the (2-2)-th stage may have a circular shape.

In an embodiment, the deposition apparatus may further include a third support part in which a third support opening is defined, and a fourth support part which is disposed on the first support part, and in which a fourth support opening is defined.

In an embodiment, the third support part may be disposed on the first support part, and the mask and the first support part may be disposed between the third support part and the fourth support part.

In an embodiment, the deposition apparatus may further include a (3-1)-th stage disposed in the third support opening, and configured to rotate about the rotation axis perpendicular to the plane, and a (3-2)-th stage which is disposed on the (3-1)-th stage, and in which a plurality of third openings are defined.

In an embodiment, the deposition apparatus may further include the plurality of sensors respectively disposed in the plurality of third openings, and the (3-2)-th stage may have a circular shape in the plan view.

In an embodiment, the deposition apparatus may further include a (4-1)-th stage disposed in the fourth support opening, and configured to rotate about the rotation axis perpendicular to the plane, and a (4-2)-th stage which is disposed on the (4-1)-th stage, and in which a plurality of fourth openings are defined.

In an embodiment, the deposition apparatus may further include the plurality of sensors respectively disposed in the plurality of fourth openings, and the (4-2)-th stage may have a circular shape in the plan view.

In an embodiment, the deposition apparatus may further include a vacuum chamber where a transparent glass substrate is disposed, the third support part may be disposed outside the vacuum chamber, and the fourth support part may be disposed inside the vacuum chamber.

In an embodiment, the deposition apparatus may further include a (3-1)-th stage disposed in the third support opening, and configured to rotate about the rotation axis perpendicular to the plane, a (3-2)-th stage which is disposed on the (3-1)-th stage, and in which a plurality of third openings are defined, and the plurality of sensors respectively disposed in the plurality of third openings.

In an embodiment, the deposition apparatus may further include a (4-1)-th stage disposed in the fourth support opening, and configured to rotate about the rotation axis perpendicular to the plane, a (4-2)-th stage which is disposed on the (4-1)-th stage, and in which a plurality of fourth openings are defined, and the plurality of sensors respectively disposed in the plurality of fourth openings.

In an embodiment, the deposition apparatus may further include a deposition source disposed under the mask, and a shutter disposed on the deposition source.

In an embodiment of the inventive concept, a thin-film deposition method includes disposing, on a first support part, a mask frame in which a frame opening is defined, disposing a mask on an upper surface of the mask frame, disposing an electrostatic chuck on the mask, disposing, on the first support part, a second support part with a first support opening defined in an upper surface and a second support opening defined in a lower surface, disposing, in the first support opening, a (1-1)-th stage configured to rotate about a rotation axis perpendicular to a plane, disposing, on the (1-1)-th stage, a (1-2)-th stage in which a plurality of first openings are defined, disposing, in the second support opening, a (2-1)-th stage configured to rotate about the rotation axis perpendicular to the plane, disposing, on the (2-1)-th stage, a (2-2)-th stage in which a plurality of second openings are defined, disposing a plurality of sensors respectively in the plurality of first openings and the plurality of second openings, moving the second support part in a first direction, measuring flatness of the electrostatic chuck and a degree of sagging of the mask, moving the electrostatic chuck in a third direction crossing both the first direction and a second direction crossing the first direction, disposing a substrate on a lower surface of the electrostatic chuck, measuring flatness of the substrate, moving the second support part in a direction opposite to the first direction, and depositing a deposition material on the substrate.

In an embodiment, the thin-film deposition method may further include disposing, on the first support part, a third support part in which a third support opening is defined and disposing, on the first support part, a fourth support part in which a fourth support opening is defined, and the mask and the first support part may be disposed between the third support part and the fourth support part.

In an embodiment, the thin-film deposition method may further include disposing, in the third support opening, a (3-1)-th stage configured to rotate about the rotation axis perpendicular to the plane, disposing, on the (3-1)-th stage, a (3-2)-th stage in which a plurality of third openings are defined, and disposing the plurality of sensors respectively in the plurality of third openings.

In an embodiment, the thin-film deposition method may further include disposing, in the fourth support opening, a (4-1)-th stage configured to rotate about the rotation axis perpendicular to the plane, disposing, on the (4-1)-th stage, a (4-2)-th stage in which a plurality of fourth openings are defined, and disposing the plurality of sensors respectively in the plurality of fourth openings.

In an embodiment, the thin-film deposition method may further include disposing a vacuum chamber which includes a transparent glass substrate, and in which the mask, the first support part, and the electrostatic chuck are disposed, disposing, outside the vacuum chamber, a third support part in which a third support opening is defined, and disposing, inside the vacuum chamber and on the first support part, a fourth support part in which a fourth support opening is defined.

In an embodiment, the thin-film deposition method may further include disposing, in the third support opening, a (3-1)-the stage configured to rotate about the rotation axis perpendicular to the plane, disposing, on the (3-1)-th stage, a (3-2)-th stage in which a plurality of third openings are defined, disposing, in the fourth support opening, a (4-1)-th stage configured to rotate about the rotation axis perpendicular to the plane, disposing, on the (4-1)-th stage, a (4-2)-th stage in which a plurality of fourth openings are defined, and disposing the plurality of sensors respectively in the plurality of third openings and the plurality of fourth openings.

In an embodiment, the thin-film deposition method may further include inspecting flatness of the electrostatic chuck, inspecting a degree of sagging of the mask, and inspecting flatness of the substrate.

In an embodiment of the inventive concept, an electronic apparatus includes a display device configured to display an image, and a processor configured to process an image signal and provide the image signal to the display device, where the display device includes a substrate manufactured by disposing, on a first support part, a mask frame in which a frame opening is defined, disposing a mask on an upper surface of the mask frame, disposing an electrostatic chuck on the mask, disposing, on the first support part, a second support part with a first support opening defined in an upper surface and a second support opening defined in a lower surface, disposing, in the first support opening, a (1-1)-th stage configured to rotate about a rotation axis perpendicular to a plane, disposing, on the (1-1)-th stage, a (1-2)-th stage in which a plurality of first openings are defined, disposing, in the second support opening, a (2-1)-th stage configured to rotate about the rotation axis perpendicular to the plane, disposing, on the (2-1)-th stage, a (2-2)-th stage in which a plurality of second openings are defined, disposing a plurality of sensors respectively in the plurality of first openings and the plurality of second openings, moving the second support part in a first direction, measuring flatness of the electrostatic chuck and a degree of sagging of the mask, moving the electrostatic chuck in a third direction crossing both the first direction and a second direction crossing the first direction, disposing a substrate on a lower surface of the electrostatic chuck, measuring flatness of the substrate, moving the second support part in a direction opposite to the first direction, and depositing a compound on the substrate.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view illustrating an embodiment of a deposition apparatus of the inventive concept;

FIGS. 2 and 3 are cross-sectional views of an embodiment of a deposition apparatus of the inventive concept;

FIGS. 4 and 5 are cross-sectional views of an embodiment of a deposition apparatus of the inventive concept;

FIG. 6 is a cross-sectional view of an embodiment of a deposition apparatus of the inventive concept;

FIGS. 7A to 7D illustrate an embodiment of a part of a thin-film deposition method according to the inventive concept;

FIGS. 8A to 8D are plan views illustrating an embodiment of an arrangement of sensors of the inventive concept;

FIG. 9 is a block diagram of an embodiment of an electronic apparatus of the inventive concept;

FIG. 10 is a schematic diagram of embodiments of an electronic apparatus of the inventive concept;

FIG. 11 is a plan view of a display panel manufactured by the deposition apparatus illustrated in FIG. 1;

FIG. 12 illustrates a cross section of any one pixel illustrated in FIG. 11; and

FIG. 13 illustrates a deposition process illustrated in FIGS. 7A to 7D.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. Also, in the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer, or section. For instance, a first element, component, region, layer, or section discussed below could be termed a second element, component, region, layer, or section without departing from the scope of the inventive concept. Similarly, a second element, component, region, layer, or section could be termed a first element, component, region, layer, or section. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms have relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components, or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skills in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the drawings.

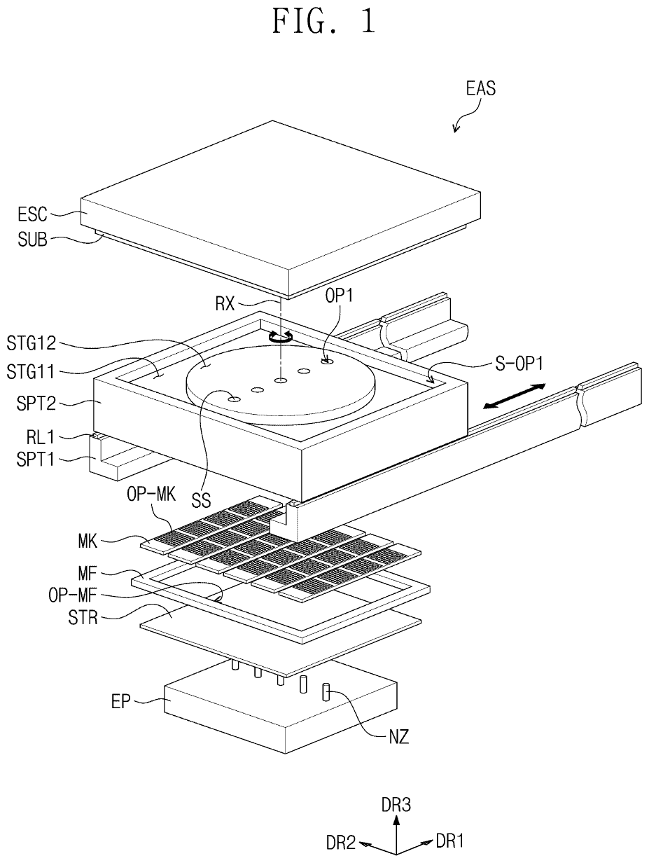

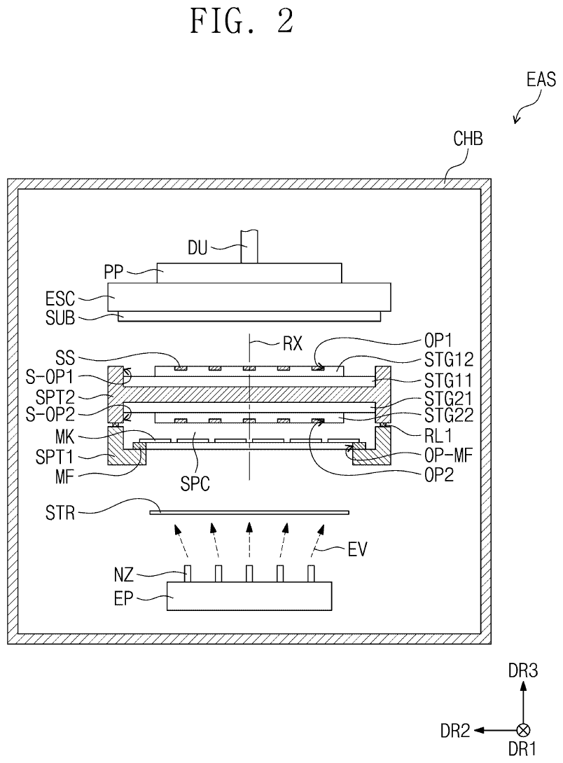

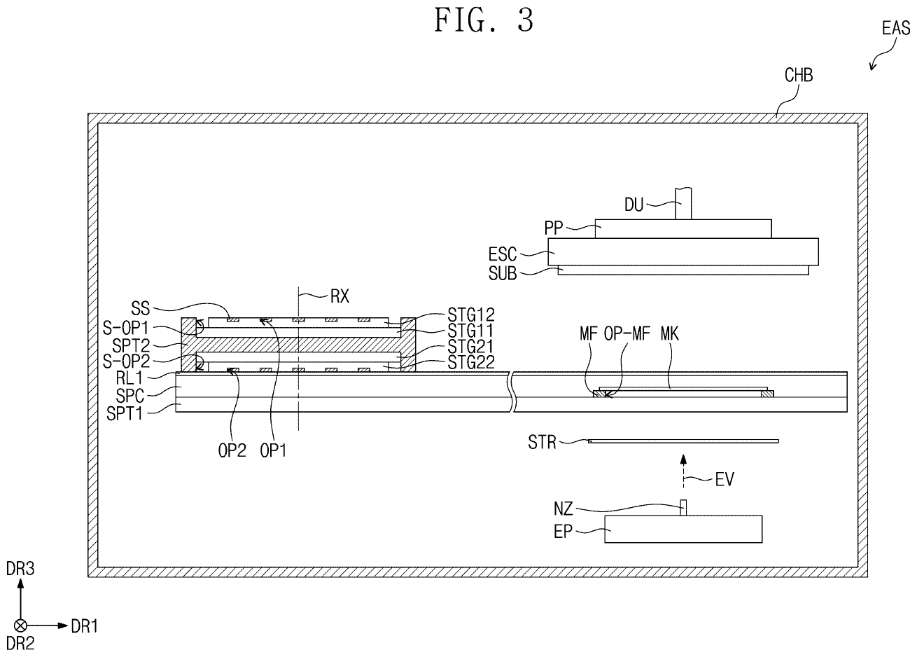

FIG. 1 is a perspective view illustrating an embodiment of a deposition apparatus of the inventive concept. FIGS. 2 and 3 are cross-sectional views of a deposition apparatus of the inventive concept. For convenience of explanation, a vacuum chamber CHB is omitted in FIG. 1. In the description, the cross-sectional views may refer to side views that show cross-sections of outer portions of the apparatus, with internal elements assumed to be visible.

Referring to FIGS. 1 to 3, a deposition apparatus EAS may include a first support part SPT1, a mask frame MF, a mask MK, an electrostatic chuck ESC, a second support part SPT2, a (1-1)-th stage STG11, a (1-2)-th stage STG12, a (2-1)-th stage STG21, a (2-2)-th stage STG22, and sensors SS.

The first support part SPT1 may support the second support part SPT2. A first rail RL1 may be disposed on the first support part SPT1. The second support part SPT2 may move along the first rail RL1 in a first direction DR1.

The mask frame MF may be disposed on the first support part SPT1. A frame opening OP-MF may be defined in the mask frame MF. The mask frame MF may have a shape of a quadrangular frame which has short sides extending in the first direction DR1 and long sides extending in a second direction DR2. In the mask frame MF having the shape of the quadrangular frame, the frame opening OP-MF may be defined. A shape of the frame opening OP-MF may be a quadrangular shape.

The mask frame MF may have a rigidity. In an embodiment, the mask frame MF may include or consist of a metal material such as stainless steel (“SUS”), invar, nickel (Ni), and cobalt (Co), for example.

The mask MK may be disposed on an upper surface of the mask frame MF. A mask opening OP-MK may be defined in the mask MK. The mask MK may extend in the first direction DR1 and may be disposed in the second direction DR2. The mask MK may have a quadrangular shape, e.g., rectangular shape which has long sides extending in the first direction DR1 and short sides extending in the second direction DR2.

Two sides of the mask MK may be connected to the mask frame MF. The mask MK may be stretched so as to cover the frame opening OP-MF. In an embodiment, the mask MK may be stretched in the first direction DR1 according to force acting in the first direction DR1 and a direction opposite to the first direction DR1, for example. The stretched mask MK may be connected to the mask frame MF through laser welding.

FIG. 1 illustrates the mask MK and the mask frame MF under the first support part SPT1, but this is for convenience of explanation. The mask MK and the mask frame MF may be disposed on the first support part SPT1 in a space SPC defined in the first support part SPT1 and the second support part SPT2.

The mask MK may include metal. In an embodiment, the mask MK may be defined as a fine metal mask, for example.

The mask opening OP-MK may be defined in the first direction DR1 and the second direction DR2. In a plan view, the mask opening OP-MK may overlap the frame opening OP-MF.

The electrostatic chuck ESC may be disposed on the mask MK. The electrostatic chuck ESC may be disposed on the second support part SPT2. A substrate SUB may be disposed under the electrostatic chuck ESC. The electrostatic chuck ESC may be disposed between the substrate SUB and a fixing member PP. The electrostatic chuck ESC may form electrostatic force by an electrostatic induction phenomenon. The electrostatic chuck ESC may chuck or de-chuck the substrate SUB via the electrostatic force.

As illustrated in FIG. 1, the electrostatic chuck ESC may have a shape corresponding to a portion of a quadrangular shape. Although not illustrated, the electrostatic chuck ESC may move back and forth in a third direction DR3 by an external motor. Accordingly, the electrostatic chuck ESC may move away from the substrate SUB or closer to the substrate SUB.

The electrostatic chuck ESC in an embodiment of the inventive concept may be a bipolar electrostatic chuck. However, this is an illustrative embodiment, and a type of the electrostatic chuck ESC according to the inventive concept is not limited thereto. In an embodiment, the electrostatic chuck ESC may be a monopolar electrostatic chuck, for example. In this case, a direct current voltage having the same polarity may be applied to a plurality of positive electrodes and a plurality of negative electrodes, of the electrostatic chuck ESC. In the monopolar electrostatic chuck, the plurality of positive electrodes and the plurality of negative electrodes may be also referred to as electrodes.

The fixing member PP may be disposed inside the vacuum chamber CHB, and may face a deposition source EP in the third direction DR3. The fixing member PP may adhere the substrate SUB to the mask MK. The fixing member PP may include magnetic substances for adhering the mask MK and the substrate SUB. In an embodiment, the magnetic substances may fix the mask MK by generating magnetic force, and the substrate SUB disposed between the mask MK and the fixing member PP may be adhered to the mask MK, for example. However, the disclosure is not limited thereto, and the fixing member PP may include a jig or robot arm for holding the mask MK.

A driving part DU may be coupled onto an upper surface of the fixing member PP. The driving part DU may have a cylindrical shape extending in the third direction DR3, but is not limited thereto and may have various shapes. The driving part DU may move back and forth in the third direction DR3, which may move the fixing member PP back and forth in the third direction DR3.

The second support part SPT2 may be disposed on the first rail RL1. The second support part SPT2 may be disposed on the first support part SPT1. The second support part SPT2 may move along the first rail RL1 in a direction parallel to the first direction DR1. A first support opening S-OP1 may be defined in an upper surface of the second support part SPT2. A second support opening S-OP2 may be defined in a lower surface of the second support part SPT2.

The (1-1)-th stage STG11 may be disposed in the first support opening S-OP1. That is, the (1-1)-th stage STG11 may be disposed in the upper surface of the second support part SPT2. The (1-1)-th stage STG11 may rotate about a rotation axis RX perpendicular to a plane.

In an embodiment, the (1-1)-th stage STG11 may be a motor rotation stage, for example. The (1-1)-th stage STG11 may use a stepping motor, and may rotate to a desired angle by controlling the number of pulses of an electrical signal. The (1-1)-th stage STG11 may control a rotation angle using a micro-step driver. The (1-1)-th stage STG11 may have a relatively high precision encoder disposed (e.g., mounted) thereon, and may receive real-time feedback on an actual rotation angle, thereby reducing errors. In addition, the (1-1)-th stage STG11 may include a reduction gear to provide relatively high torque and stable rotation, and may also be controlled remotely through a computer or micro-controller.

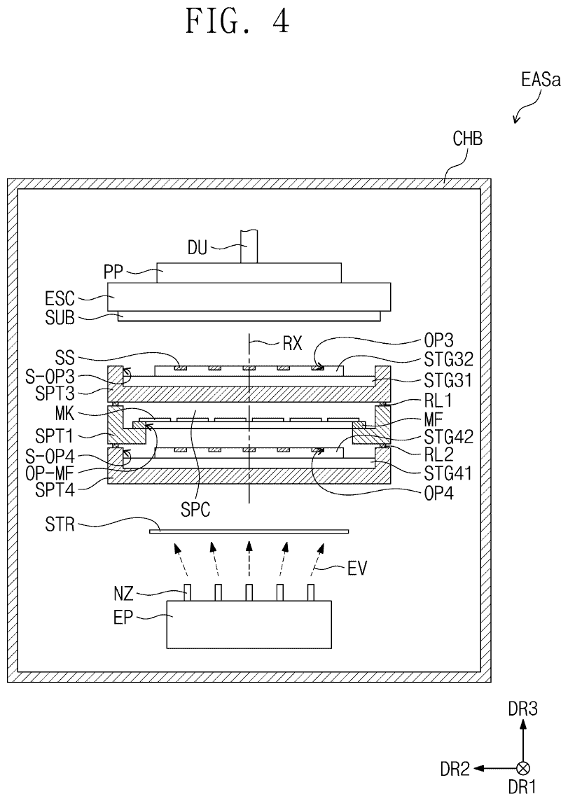

Hereinafter, the (2-1)-th stage STG21, a (3-1)-th stage STG31 (refer to FIG. 4), and a (4-1)-th stage STG41 (refer to FIG. 4) may be the same motor rotation stage as the (1-1)-th stage STG11.

The (1-2)-th stage STG12 may be disposed on the (1-1)-th stage STG11. A plurality of first openings OP1 may be defined in the (1-2)-th stage STG12. The sensors SS may be respectively disposed in the first openings OP1. The (1-2)-th stage STG12 may have a circular shape in a plan view (e.g., when viewed in the third direction DR3).

The (1-2)-th stage STG12 may be disposed on the (1-1)-th stage STG11, and may rotate in the same direction as the direction where the (1-1)-th stage STG11 rotates when the (1-1)-th stage STG11 rotates about the rotation axis RX.

While the (1-2)-th stage STG12 is rotating, the sensors SS respectively disposed in the first openings OP1 may measure flatness of the substrate SUB or the electrostatic chuck ESC. In an embodiment, the sensors SS may be a laser interferometer sensor, confocal laser microscope sensor, and laser triangulation sensor, for example. The sensors SS may measure flatness and roughness of a process target by analyzing a pattern of light reflected on a planar surface of the process target. The sensors SS to be described below may measure the flatness and roughness of the process target.

When the sensors SS measure the flatness of the substrate SUB or the electrostatic chuck ESC, the sensors SS may overlap the substrate SUB or the electrostatic chuck ESC in the third direction DR3. When the sensors SS do not measure the flatness of the substrate SUB or the electrostatic chuck ESC, the sensors SS may not overlap the substrate SUB or the electrostatic chuck ESC in the third direction DR3. In an embodiment, referring to FIG. 3, the second support part SPT2 may move in a direction opposite to the first direction DR1, so that the sensors SS may not overlap the substrate SUB or the electrostatic chuck ESC, for example.

The (2-1)-th stage STG21 may be disposed in the second support opening S-OP2. That is, the (2-1)-th stage STG21 may be disposed in the lower surface of the second support part SPT2. The (2-1)-th stage STG21 may rotate about the rotation axis RX perpendicular to a plane.

The (2-2)-th stage STG22 may be disposed on the (2-1)-th stage STG21. A plurality of second openings OP2 may be defined in the (2-2)-th stage STG22. The sensors SS may be respectively disposed in the second openings OP2. The (1-2)-th stage STG12 may have a circular shape in a plan view (e.g., when viewed in the third direction DR3).

The (2-2)-th stage STG22 may be disposed on the (2-1)-th stage STG21, and may rotate in the same direction as the direction where the (2-1)-th stage STG21 rotates when the (2-1)-th stage STG21 rotates about the rotation axis RX.

While the (2-2)-th stage STG22 is rotating, the sensors SS respectively disposed in the second openings OP2 may measure a degree of sagging of the mask MK. In an embodiment, the sensors SS may be a laser interferometer sensor, confocal laser microscope sensor, and laser triangulation sensor, for example.

When the sensors SS measure the degree of sagging of the mask MK, the sensors SS may overlap the mask MK in the third direction DR3. When the sensors SS do not measure the degree of sagging of the mask, the sensors SS may not overlap the mask MK in the third direction DR3. In an embodiment, referring to FIG. 3, the second support part SPT2 may move in a direction opposite to the first direction DR1, so that the sensors SS may not overlap the mask MK, for example.

The deposition apparatus EAS may further include the deposition source EP and a shutter STR.

The deposition source EP may be disposed inside the vacuum chamber CHB. The deposition source EP may include a storage space where a deposition material EV is accommodated and at least one nozzle NZ. The deposition material EV may include metal, an inorganic material, or an organic material which is capable of sublimation or vaporization.

In an embodiment, the deposition material EV may include an organic light-emitting material for formation of a light-emitting layer EML (refer to FIG. 13). The sublimated or vaporized deposition material EV may be sprayed toward the substrate SUB through the nozzle NZ, for example. The deposition material EV may pass through the mask openings OP-MK of the mask MK to be patterned and deposited on the substrate SUB.

The shutter STR may prevent the deposition material EV from being sprayed when the deposition material EV is patterned onto the substrate SUB through the mask MK. This may control patterning of the deposition material EV on the substrate SUB.

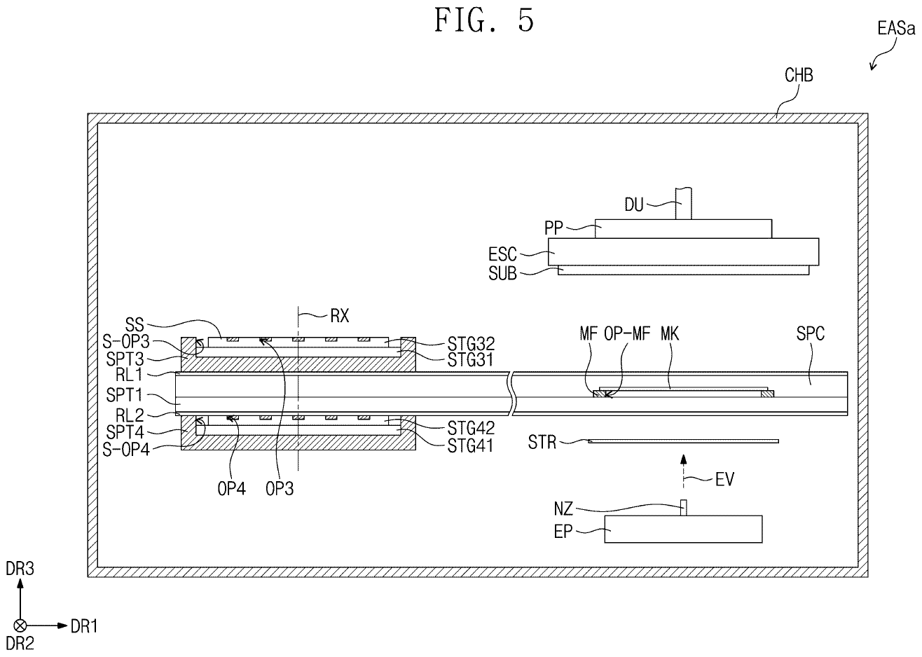

FIGS. 4 and 5 are cross-sectional views of an embodiment of a deposition apparatus of the inventive concept.

Referring to FIGS. 4 and 5, a deposition apparatus EASa may further include a third support part SPT3 and a fourth support part SPT4.

The third support part SPT3 may be disposed on a first rail RL1. The third support part SPT3 may be disposed on a first support part SPT1. The third support part SPT3 may move along the first rail RL1 in a direction parallel to a first direction DR1. A third support opening S-OP3 may be defined in the third support part SPT3. That is, the third support opening S-OP3 may be defined in an upper surface of the third support part SPT3.

A (3-1)-th stage STG31 may be disposed in the third support opening S-OP3. That is, the (3-1)-th stage STG31 may be disposed in the upper surface of the third support part SPT3. The (3-1)-th stage STG31 may rotate about a rotation axis RX perpendicular to a plane.

A (3-2)-th stage STG32 may be disposed on the (3-1)-th stage STG31. A plurality of third openings OP3 may be defined in the (3-2)-th stage STG32. Sensors SS may be respectively disposed in the third openings OP3. The (3-2)-th stage STG32 may have a circular shape in a plan view (e.g., when viewed in a third direction DR3).

The (3-2)-th stage STG32 may be disposed on the (3-1)-th stage STG31, and may rotate in the same direction as the direction where the (3-1)-th stage STG31 rotates when the (3-1)-th stage STG31 rotates about the rotation axis RX.

While the (3-2)-th stage STG32 is rotating, the sensors SS respectively disposed in the third openings OP3 may measure flatness of a substrate SUB or an electrostatic chuck ESC.

The fourth support part SPT4 may be disposed on a lower surface of the first support part SPT1. In an embodiment, a mask MK and the first support part SPT1 may be disposed between the third support part SPT3 and the fourth support part SPT4, for example.

The fourth support part SPT4 may be disposed on a second rail RL2. That is, the fourth support part SPT4 may move along the second rail RL2 in a direction parallel to the first direction DR1. A fourth support opening S-OP4 may be defined in the fourth support part SPT4. That is, the fourth support opening S-OP4 may be defined in an upper surface of the fourth support part SPT4.

A (4-1)-th stage STG41 may be disposed in the fourth support opening S-OP4. That is, the (4-1)-th stage STG41 may be disposed in the upper surface of the fourth support part SPT4. The (4-1)-th stage STG41 may rotate about the rotation axis RX perpendicular to a plane.

A (4-2)-th stage STG42 may be disposed on the (4-1)-th stage STG41. A plurality of fourth openings OP4 may be defined in the (4-2)-th stage STG42. The sensors SS may be respectively disposed in the fourth openings OP4. The (4-2)-th stage STG42 may have a circular shape in a plan view (e.g., when viewed in the third direction DR3).

The (4-2)-th stage STG42 may be disposed on the (4-1)-th stage STG41, and may rotate in the same direction as the direction where the (4-1)-th stage STG41 rotates when the (4-1)-th stage STG41 rotates about the rotation axis RX.

While the (4-2)-th stage STG42 is rotating, the sensors SS respectively disposed in the fourth openings OP4 may measure a degree of sagging of the mask MK.

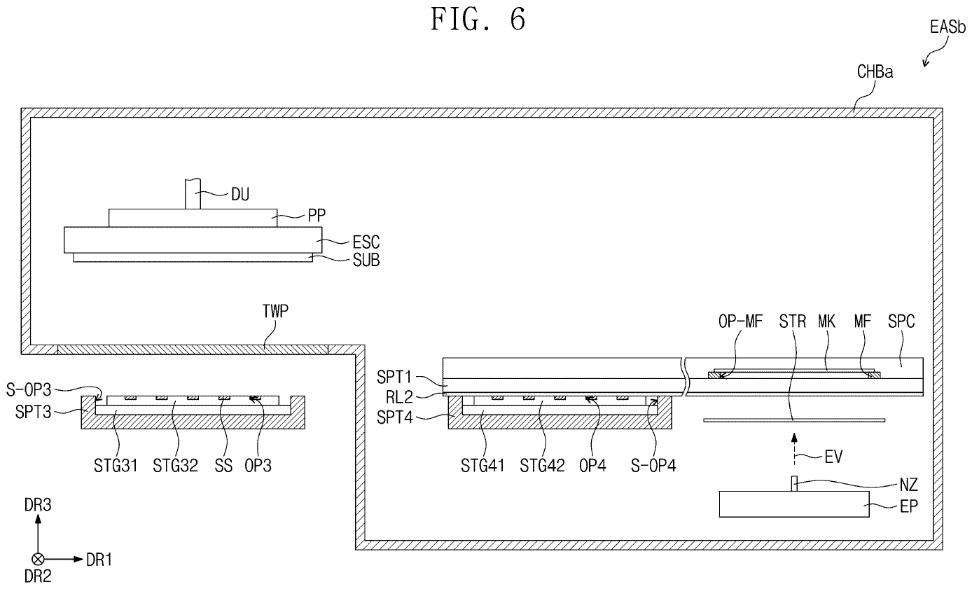

FIG. 6 is a cross-sectional view of an embodiment of a deposition apparatus of the inventive concept.

Referring to FIG. 6, a deposition apparatus EASb may further include a vacuum chamber CHBa where a transparent glass substrate TWP is disposed, a third support part SPT3, and a fourth support part SPT4.

The third support part SPT3 may be disposed outside the vacuum chamber CHBa. Although not illustrated, the third support part SPT3 may be fixed and disposed outside the vacuum chamber CHBa. A third support opening S-OP3 may be defined in the third support part SPT3. That is, the third support opening S-OP3 may be defined in an upper surface of the third support part SPT3.

A (3-1)-th stage STG31 may be disposed in the third support opening S-OP3. That is, the (3-1)-th stage STG31 may be disposed in the upper surface of the third support part SPT3. The (3-1)-th stage STG31 may rotate about a rotation axis RX perpendicular to a plane.

A (3-2)-th stage STG32 may be disposed on the (3-1)-th stage STG31. A plurality of third openings OP3 may be defined in the (3-2)-th stage STG32. Sensors SS may be respectively disposed in the third openings OP3. The (3-2)-th stage STG32 may have a circular shape in a plan view (e.g., when viewed in a third direction DR3).

The (3-2)-th stage STG32 may be disposed on the (3-1)-th stage STG31, and may rotate in the same direction as the direction where the (3-1)-th stage STG31 rotates when the (3-1)-th stage STG31 rotates about the rotation axis RX.

While the (3-2)-th stage STG32 is rotating, the sensors SS respectively disposed in the third openings OP3 may measure flatness of a substrate SUB or an electrostatic chuck ESC. Light used when the sensors SS measure the flatness of the substrate SUB or the electrostatic chuck ESC may be incident on a planar surface of the substrate SUB or the electrostatic chuck ESC through the transparent glass substrate TWP, and the light reflected on the planar surface of the substrate SUB or the electrostatic chuck ESC may be incident on the sensors SS through the transparent glass substrate TWP.

The fourth support part SPT4 may be disposed inside the vacuum chamber CHBa. The fourth support part SPT4 may be disposed on a lower surface of a first support part SPT1. In an embodiment, a mask MK may be disposed between the first support part SPT1 and the fourth support part SPT4, for example.

The fourth support part SPT4 may be disposed on a second rail RL2. That is, the fourth support part SPT4 may move along the second rail RL2 in a direction parallel to a first direction DR1. A fourth support opening S-OP4 may be defined in the fourth support part SPT4. That is, the fourth support opening S-OP4 may be defined in an upper surface of the fourth support part SPT4.

A (4-1)-th stage STG41 may be disposed in the fourth support opening S-OP4. That is, the (4-1)-th stage STG41 may be disposed in the upper surface of the fourth support part SPT4. The (4-1)-th stage STG41 may rotate about the rotation axis RX perpendicular to a plane.

A (4-2)-th stage STG42 may be disposed on the (4-1)-th stage STG41. A plurality of fourth openings OP4 may be defined in the (4-2)-th stage STG42. The sensors SS may be respectively disposed in the fourth openings OP4. The (4-2)-th stage STG42 may have a circular shape in a plan view (e.g., when viewed in the third direction DR3).

The (4-2)-th stage STG42 may be disposed on the (4-1)-th stage STG41, and may rotate in the same direction as the direction where the (4-1)-th stage STG41 rotates when the (4-1)-th stage STG41 rotates about the rotation axis RX.

While the (4-2)-th stage STG42 is rotating, the sensors SS respectively disposed in the fourth openings OP4 may measure a degree of sagging of the mask MK.

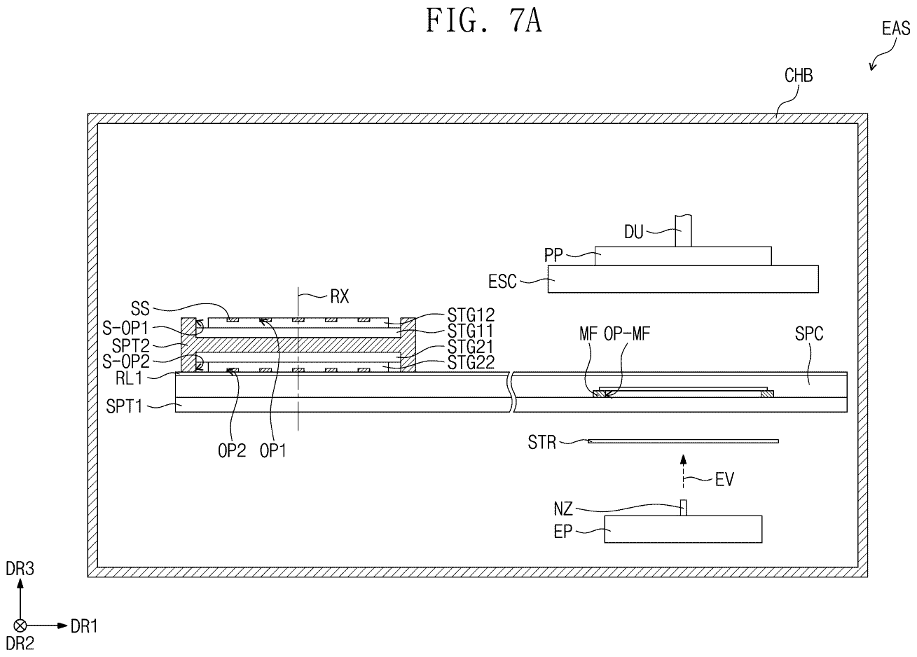

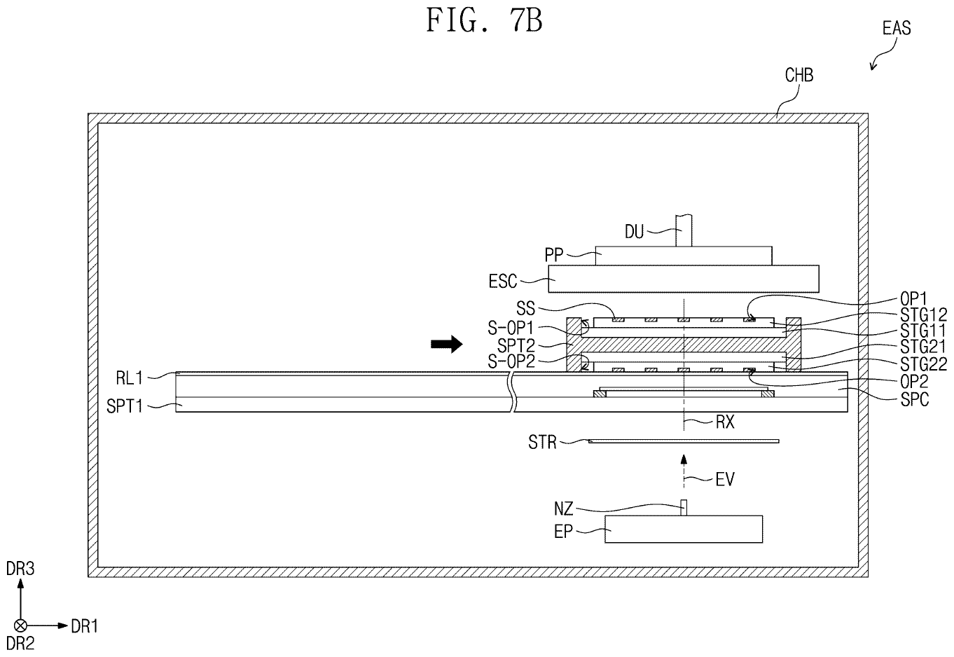

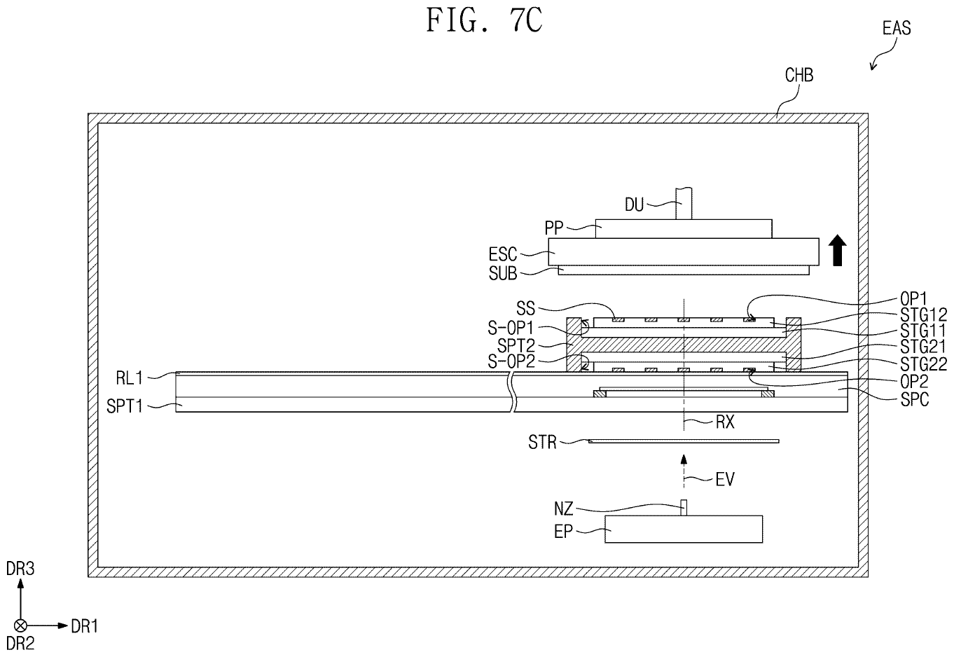

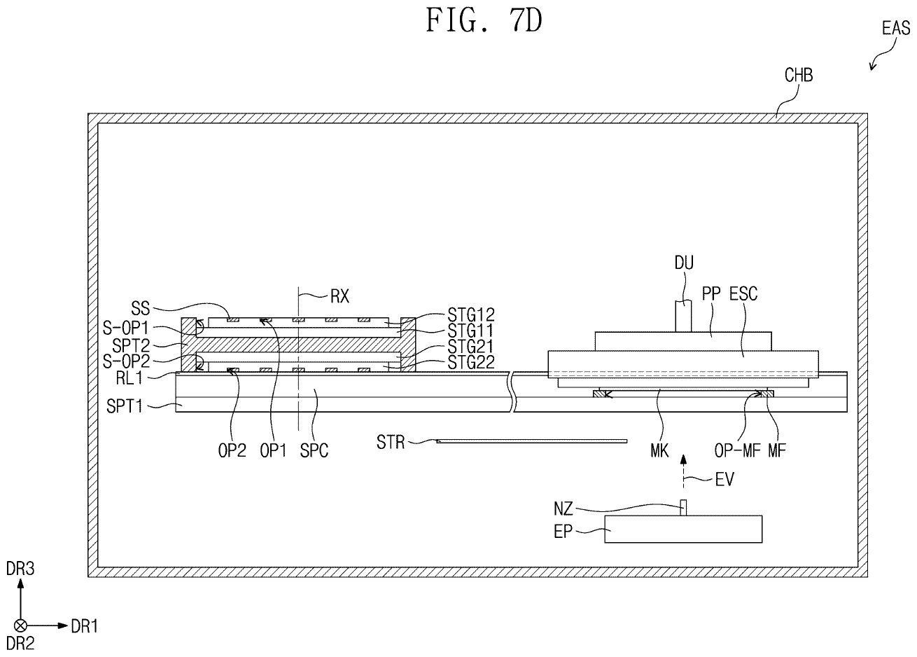

FIGS. 7A to 7D illustrate an embodiment of a part of a thin-film deposition method according to the inventive concept.

Referring to FIG. 7A, a thin-film deposition method may include an operation of disposing, on a first support part SPT1, a mask frame MF where a frame opening OP-MF is defined. The thin-film deposition method may include an operation of disposing a mask MK on an upper surface of the mask frame MF. The thin-film deposition method may include an operation of disposing an electrostatic chuck ESC on the mask MK. The thin-film deposition method may include an operation of disposing, on the first support part SPT1, a second support part SPT2 with a first support opening S-OP1 defined in an upper surface and a second support opening S-OP2 defined in a lower surface.

The thin-film deposition method may include an operation of disposing, in the first support opening S-OP1, a (1-1)-th stage STG11 which rotates about a rotation axis RX perpendicular to a plane. The thin-film deposition method may include an operation of disposing, on the (1-1)-th stage STG11, a (1-2)-th stage STG12 where a plurality of first openings OP1 are defined.

The thin-film deposition method may include an operation of disposing, in the second support opening S-OP2, a (2-1)-th stage STG21 which rotates about the rotation axis RX perpendicular to a plane. The thin-film deposition method may include an operation of disposing, on the (2-1)-th stage STG21, a (2-2)-th stage STG22 where a plurality of second openings OP2 are defined. The thin-film deposition method may include an operation of disposing a plurality of sensors SS respectively in the first openings OP1 and the second openings OP2.

Referring to FIG. 7B, the thin-film deposition method may include an operation of moving the second support part SPT2 in a first direction DR1. Since the second support part SPT2 moves in the first direction DR1, the (1-1)-th stage STG11 disposed in the first support opening S-OP1 of the second support part SPT2, the (1-2)-th stage STG12, the (2-1)-th stage STG21 disposed in the second support opening S-OP2, and the (2-2)-th stage STG22 may move in the first direction DR1.

The thin-film deposition method may include an operation of measuring flatness of the electrostatic chuck ESC and a degree of sagging of the mask MK. The second support part SPT2 may move in the first direction DR1, and thus the second support part SPT2 may overlap the electrostatic chuck ESC and the mask MK in a third direction DR3.

The sensors SS disposed in the first openings OP1 of the (1-2)-th stage STG12 may measure flatness of a planar surface of the electrostatic chuck ESC. The (1-1)-th stage STG11 may rotate about the rotation axis RX, and the (1-2)-th stage STG12 may also rotate according to the rotation of the (1-1)-th stage STG11. In addition, the sensors SS may measure the flatness of the electrostatic chuck ESC while rotating according to the rotation of the (1-2)-th stage STG12.

The thin-film deposition method may further include an operation of inspecting the flatness of the electrostatic chuck ESC. After the sensors SS inspect the flatness of the electrostatic chuck ESC, it may be determined whether or not flatness criteria of the electrostatic chuck ESC are fulfilled. When the flatness criteria of the electrostatic chuck ESC are not fulfilled, the process may be discontinued, and then the flatness of the electrostatic chuck ESC may be improved.

The sensors SS disposed in the second openings OP2 of the (2-2)-th stage STG22 may measure a degree of sagging of the mask MK. The (2-1)-th stage STG21 may rotate about the rotation axis RX, and the (2-2)-th stage STG22 may also rotate according to the rotation of the (2-1)-th stage STG21. In addition, the sensors SS may measure the degree of sagging of the mask MK while rotating according to the rotation of the (2-2)-th stage STG22.

The thin-film deposition method may further include an operation of inspecting a degree of sagging of the mask MK. After the sensors SS inspect the degree of sagging of the mask MK, it may be determined whether or not sagging criteria of the mask MK are fulfilled. When the sagging criteria of the mask MK are not fulfilled, the process may be discontinued, and then sagging of the mask MK may be improved.

Referring to FIG. 7C, the thin-film deposition method may include an operation of moving the electrostatic chuck ESC in the third direction DR3 crossing both the first direction DR1 and a second direction DR2 crossing the first direction DR1. The thin-film deposition method may include an operation of disposing a substrate SUB on a lower surface of the electrostatic chuck ESC. After the electrostatic chuck ESC moves in the third direction DR3, the substrate SUB may be disposed on the lower surface of the electrostatic chuck ESC.

The thin-film deposition method may include an operation of measuring flatness of the substrate SUB. The sensors SS disposed in the first openings OP1 of the (1-2)-th stage STG12 may measure flatness of a planar surface of the substrate SUB. The (1-1)-th stage STG11 may rotate about the rotation axis RX, and (1-2)-th stage STG12 may also rotate according to the rotation of the (1-1)-th stage STG11. In addition, the sensors SS may measure the flatness of the substrate SUB while rotating according to the rotation of the (1-2)-th stage STG12.

The thin-film deposition method may further include an operation of inspecting the flatness of the substrate SUB. After the sensors SS inspect the flatness of the substrate SUB, it may be determined whether or not flatness criteria of the substrate SUB are fulfilled. When the flatness criteria of the substrate SUB are not fulfilled, the process may be discontinued, and then the flatness of the substrate SUB may be improved. The reliability of the process may be improved through the thin-film deposition method in which the sensors SS measure flatness or a degree of sagging of a process target during the process, and when certain criteria are not fulfilled, flatness or sagging may be improved during the process.

Referring to FIG. 7D, the thin-film deposition method may include an operation of moving the second support part SPT2 in a direction opposite to the first direction DR1. When flatness of the electrostatic chuck ESC and the substrate SUB fulfills certain criteria, and a degree of sagging of the mask MK fulfills certain criteria, a thin-film deposition process may be performed. The second support part SPT2 may move in the direction opposite to the first direction DR1, thereby preparing for the thin-film deposition process.

The thin-film deposition method may include an operation of moving the substrate SUB in a direction opposite to the third direction DR3. The substrate SUB may move in the direction opposite to the third direction DR3 to contact the mask MK. The thin-film deposition method may include an operation of depositing a deposition material EV onto the substrate SUB. The deposition material EV may be patterned on the substrate SUB through the mask MK.

Referring to FIG. 5 and FIGS. 7A to 7D, the thin-film deposition method may further include an operation of disposing, on the first support part SPT1, a third support part SPT3 where a third support opening S-OP3 is defined. The thin-film deposition method may further include an operation of disposing, on the first support part SPT1, a fourth support part SPT4 where a fourth support opening S-OP4 is defined. The mask MK and the first support part SPT1 may be disposed between the third support part SPT3 and the fourth support part SPT4.

The thin-film deposition method may further include an operation of disposing, in the third support opening S-OP3, a (3-1)-th stage STG31 which rotates about the rotation axis RX perpendicular to a plane. The thin-film deposition method may further include an operation of disposing, on the (3-1)-th stage STG31, a (3-2)-th stage STG32 where a plurality of third openings OP3 are defined. The thin-film deposition method may further include an operation of disposing the sensors SS respectively in the third openings OP3.

The thin-film deposition method may further include an operation of disposing, in the fourth support opening S-OP4, a (4-1)-th stage STG41 which rotates about the rotation axis RX perpendicular to a plane. The thin-film deposition method may further include an operation of disposing, on the (4-1)-th stage STG41, a (4-2)-th stage STG42 where a plurality of fourth openings OP4 are defined. The thin-film deposition method may further include an operation of disposing the sensors SS respectively in the fourth openings OP4.

Referring to FIG. 6 and FIGS. 7A to 7D, the thin-film deposition method may include an operation of disposing a vacuum chamber CHBa which includes a transparent glass substrate TWP and in which the mask MK, the first support part SPT1, and the electrostatic chuck ESC are disposed. The thin-film deposition method may include an operation of disposing, outside the vacuum chamber CHBa, the third support part SPT3 where the third support opening S-OP3 is defined. The thin-film deposition method may further include an operation of disposing, inside the vacuum chamber CHBa and on the first support part SPT1, the fourth support part SPT4 where the fourth support opening S-OP4 is defined.

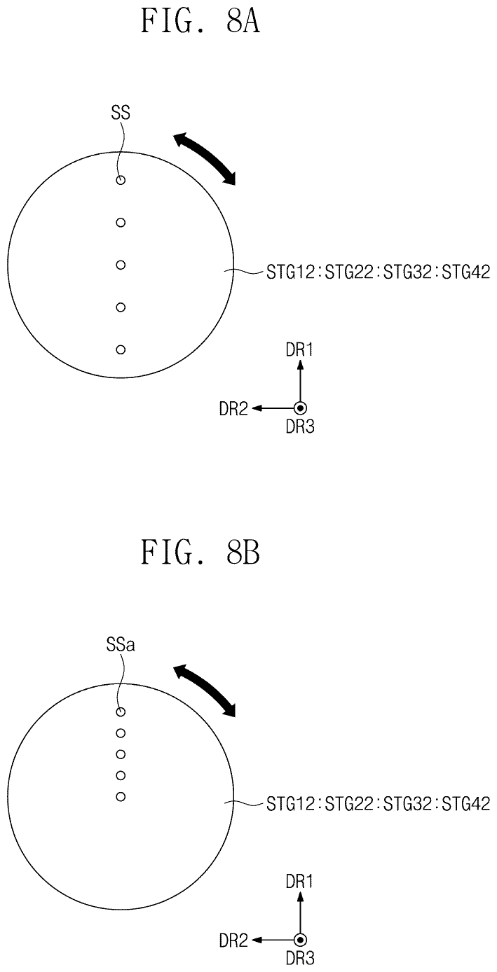

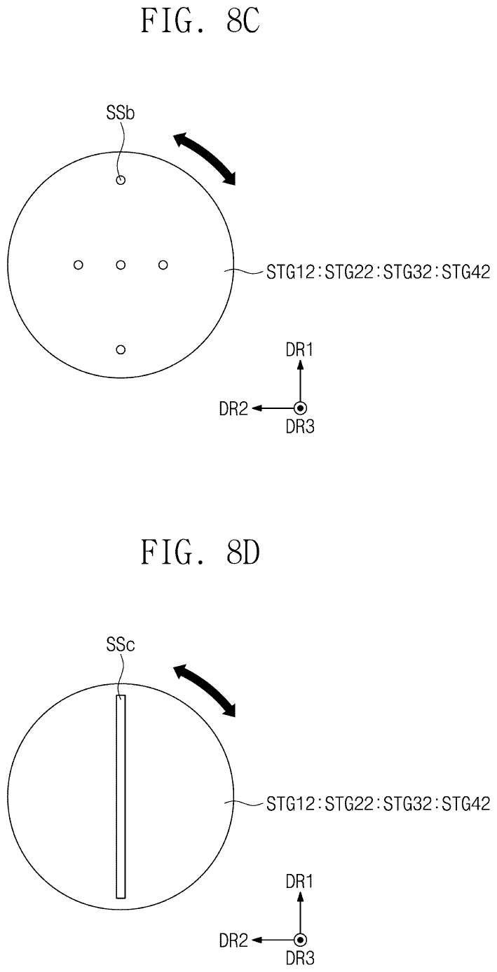

FIGS. 8A to 8D are plan views illustrating an embodiment of an arrangement of sensors of the inventive concept.

Referring to FIG. 8A, sensors SS may be disposed on a (1-2)-th stage STG12, a (2-2)-th stage STG22, a (3-2)-th stage STG32, and a (4-2)-th stage STG42. Hereinafter, when explaining with reference to FIGS. 8A to 8D, the sensors SS being disposed on the (1-2)-th stage STG12 indicates that sensors SS may also be disposed on the (2-2)-th stage STG22, the (3-2)-th stage STG32, and the (4-2)-th stage STG42.

On a (1-2)-th stage STG12 with a circular shape, the sensors SS may be arranged on a diameter at equal intervals in a direction parallel to a first direction DR1. FIG. 8A illustrates that the sensors SS are arranged on the diameter at equal intervals in the direction parallel to the first direction DR1, but the direction may not be parallel to the first direction DR1 as long as the sensors SS are disposed on the diameter of the (1-2)-th stage STG12.

Referring to FIG. 8B, on a (1-2)-th stage STG12 with a circular shape, sensors SSa may be arranged on a radius at equal intervals in a direction parallel to a first direction DR1. FIG. 8B illustrates that the sensors SSa are arranged on the radius at equal intervals in the direction parallel to the first direction DR1, but the direction may not be parallel to the first direction DR1 as long as the sensors SSa are disposed on the radius of the (1-2)-th stage STG12.

Referring to FIG. 8C, on a (1-2)-th stage STG12 with a circular shape, sensors SSb may be arranged on a diameter at equal intervals in a direction parallel to a first direction DR1 and a direction parallel to a second direction DR2. FIG. 8C illustrates that sensors SSb are arranged on the diameter at equal intervals in the direction parallel to the first direction DR1 and the direction parallel to the second direction DR2, but the direction where the sensors SSb are arranged may not be parallel to the first direction DR1 and the second direction DR2 as long as the sensors SSb are disposed on the diameter of the (1-2)-th stage STG12, and an interval between the sensors SSb disposed in the direction parallel to the first direction DR1 has a constant ratio to an interval between the sensors SSb disposed in the direction parallel to the second direction DR2.

Referring to FIG. 8D, on a (1-2)-th stage STG12 with a circular shape, a sensor SSc may extend in a direction parallel to a first direction DR1 to be disposed on a diameter. FIG. 8D illustrates the sensor SSc extending in the direction parallel to the first direction DR1, but the direction may not be parallel to the first direction DR1 as long as the sensor SSc is disposed on the diameter of the (1-2)-th stage STG12.

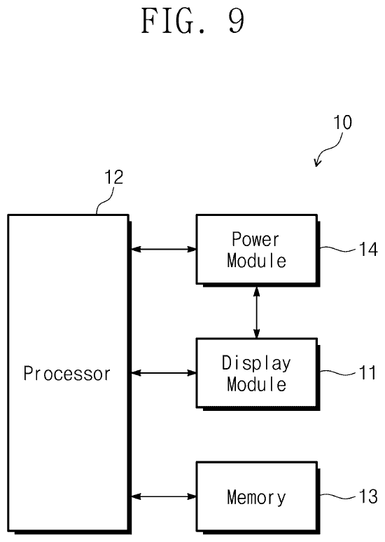

FIG. 9 is a block diagram of an embodiment of an electronic apparatus of the inventive concept.

Referring to FIG. 9, an electronic apparatus 10 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), or a controller. The processor 12 may process an image signal and provide the image signal to a display device.

In the memory 13, data information desired for an operation of the processor 12 or the display module 11 may be stored. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or battery unit, and a power conversion module which converts the power provided by the power supply module and generates power desired for an operation of the electronic apparatus 10.

At least one of the respective components of the electronic apparatus 10 described above may be included within the display device according to the aforementioned embodiments. In addition, some of individual modules functionally included within one module may be included within the display device, and others may be provided separately from the display device. In an embodiment, the display device may include the display module 11, and the processor 12, the memory 13, and the power module 14 may be provided as a form of another device within the electronic apparatus 10 other than the display device, for example.

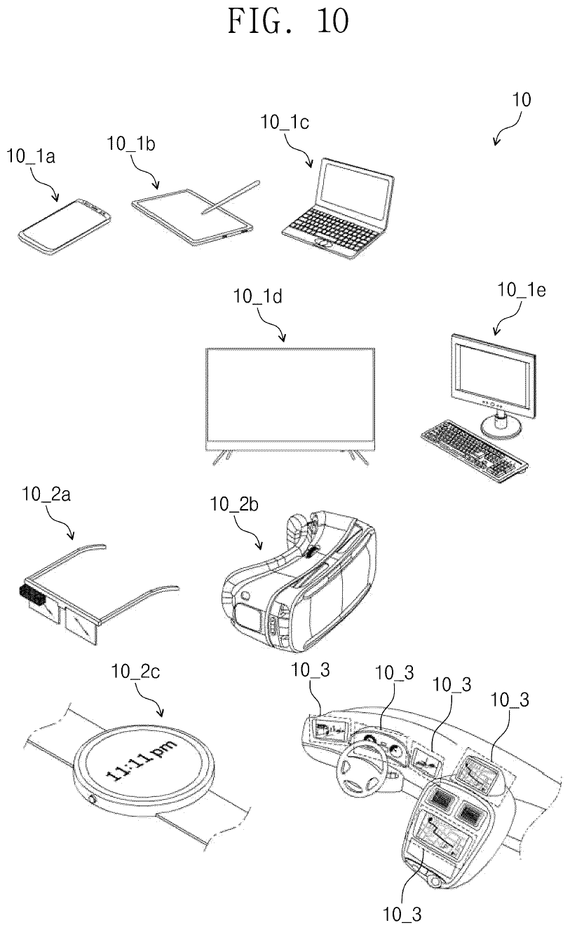

FIG. 10 shows schematic diagrams of embodiments of an electronic apparatus of the inventive concept.

Referring to FIG. 10, various electronic apparatuses in embodiments to which a display device is applied may include not only an electronic apparatus for displaying an image such as a smart phone 10_1a, a tablet personal computer (“PC”) 10_1b, a laptop computer 10_1c, a television (“TV”) 10_1d, and a monitor 10_1e for a desk, but also a wearable electronic apparatus including a display module such as smart glasses 10_2a, a head-mounted display 10_2b, and a smart watch 10_2c, and an electronic apparatus 10_3 for vehicles including a display module such as a room mirror display and a center information display (“CID”), which is disposed on a car's instrument cluster, center fascia, and dashboard. The electronic apparatus may provide an image, and may include the display device.

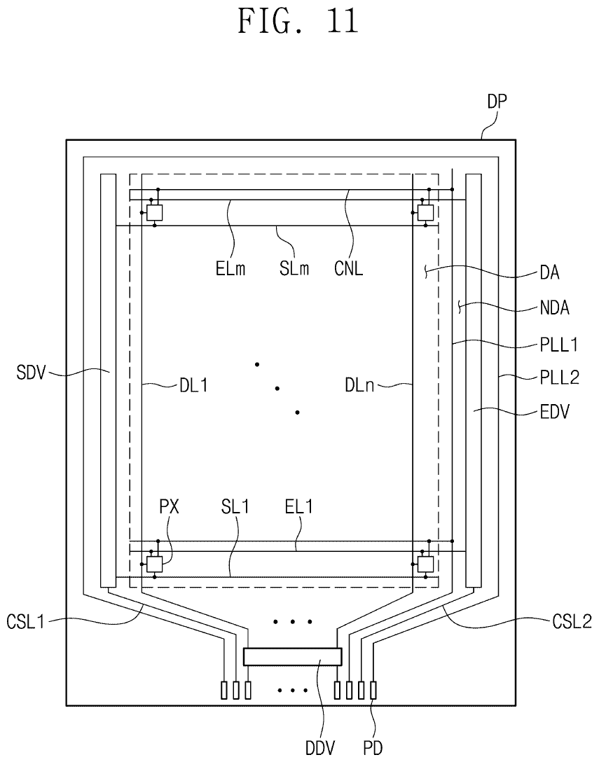

FIG. 11 is a plan view of a display panel manufactured by the deposition apparatus illustrated in FIG. 1.

A display panel DP may have a quadrangular shape, e.g., rectangular shape with short sides and long sides, but the shape of the display panel DP is not limited thereto. The display panel DP may include a display portion DA and a non-display portion NDA surrounding the display portion DA.

The display panel DP may be an emissive display panel. The display panel DP may be an organic light-emitting display panel or a quantum dot light-emitting display panel. A light-emitting layer of the organic light-emitting display panel may include an organic light-emitting material. A light-emitting layer of the quantum dot light-emitting display panel may include quantum dots, quantum rods, or the like. Hereinafter, the display panel DP will be described as an organic light-emitting display panel.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, first and second power lines PLL1 and PLL2, connection lines CNL, and a plurality of pads PD. Here, m and n are natural numbers.

The pixels PX may be disposed in the display portion DA. A scan driver SDV and an emission driver EDV may be disposed in the non-display portion NDA next (adjacent) to the respective long sides of the display panel DP. A data driver DDV may be disposed in the non-display portion NDA next (adjacent) to any one short side of the short sides of the display panel DP. In a plan view, the data driver DDV may be next (adjacent) to a lower end of the display panel DP.

The scan lines SL1 to SLm may extend in a first direction DR1 to be connected to the pixels PX and the scan driver SDV. The data lines DL1 to DLn may extend in a second direction DR2 to be connected to the pixels PX and the data driver DDV. The emission lines EL1 to ELm may extend in the first direction DR1 to be connected to the pixels PX and the emission driver EDV.

The first power line PLL1 may extend in the second direction DR2 and may be disposed in the non-display portion NDA. The first power line PLL1 may be disposed between the display portion DA and the emission driver EDV, but is not limited thereto and may be disposed between the display portion DA and the scan driver SDV.

The connection lines CNL may extend in the first direction DR1 and may be arranged in the second direction DR2. The connection lines CNL may be connected to the first power line PLL1 and the pixels PX. A first voltage may be applied to the pixels PX through the first power line PLL1 and the connection lines CNL which are connected to each other.

The second power line PLL2 may be disposed in the non-display portion NDA. The second power line PLL2 may extend along the long sides of the display panel DP and a remaining (the other) short side, of the display panel DP, where the data driver DDV is not disposed. The second power line PLL2 may be disposed outside the scan driver SDV and the emission driver EDV.

Although not illustrated, the second power line PLL2 may extend toward the display portion DA to be connected to the pixels PX. A second voltage having a lower level than the first voltage may be applied to the pixels PX through the second power line PLL2.

The first control line CSL1 may be connected to the scan driver SDV, and in a plan view, may extend toward the lower end of the display panel DP. The second control line CSL2 may be connected to the emission driver EDV, and in a plan view, may extend toward the lower end of the display panel DP. The data driver DDV may be disposed between the first control line CSL1 and the second control line CSL2.

The pads PD may be disposed on the display panel DP. The pads PD may be more next (adjacent) to the lower end of the display panel DP than the data driver DDV. The data driver DDV, the first power line PLL1, the second power line PLL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

In the aforementioned substrate SUB, unit regions corresponding to the display panel DP may be defined. Light-emitting elements may be formed in the unit regions, and then the unit regions may be cut off. Accordingly, the display panel DP illustrated in FIG. 11 may be manufactured.

Although not illustrated, a timing controller for controlling operations of the scan driver SDV, the data driver DDV, and the emission driver EDV and a voltage generator for generating the first and second voltages may be disposed on a printed circuit board. The timing controller and the voltage generator may be connected to the corresponding pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The emission driver EDV may generate a plurality of emission signals, and the emission signals may be applied to the pixels PX through the emission lines EL1 to ELm.

The pixels PX may receive the data voltages in response to the scan signals. The pixels PX may display an image by emitting light with luminance corresponding to the data voltages in response to the emission signals. The emission time of the pixels PX may be controlled by the emission signals.

The aforementioned wirings may include the data lines DL1 to DLn. The pads connected to the aforementioned wirings may include the pads PD illustrated in FIG. 11. The display panel DP where light-emitting layers of the pixels PX are not formed may be defined as the aforementioned substrate SUB.

A cross-sectional structure of the substrate SUB where the light-emitting layers are not formed will be described with reference to FIG. 13 below. The pads PD may be formed in the substrate SUB, and the substrate SUB may be defined as a state where the printed circuit board is not connected.

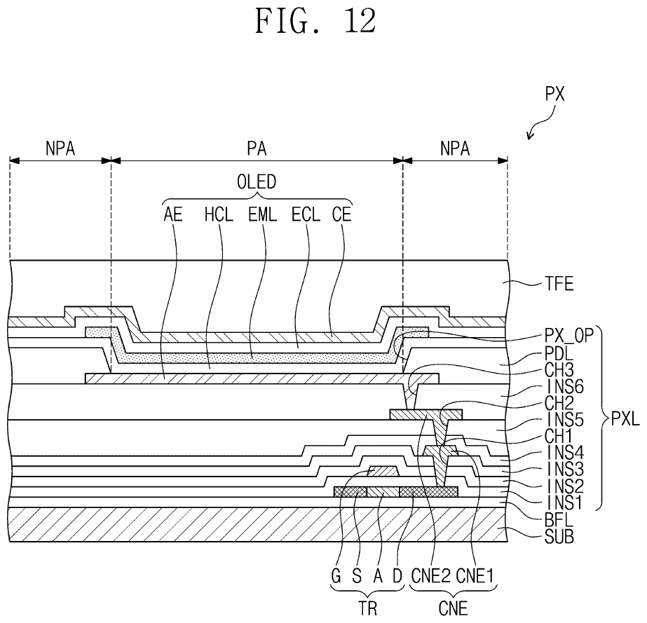

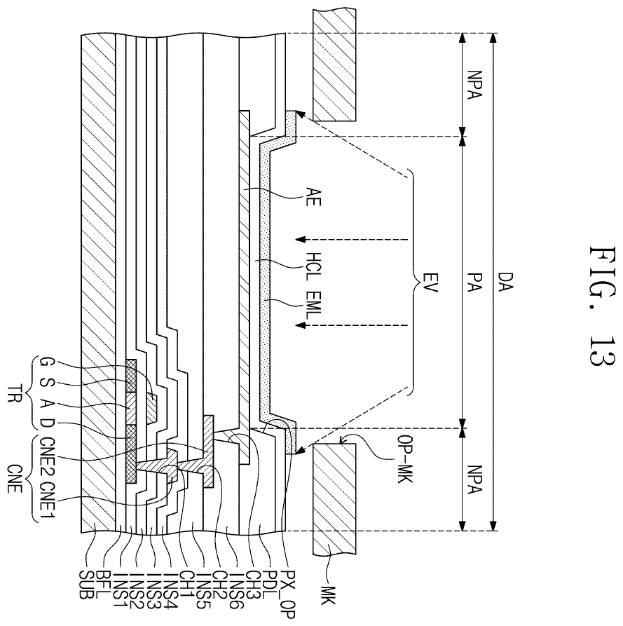

FIG. 12 illustrates a cross section of any one pixel illustrated in FIG. 11.

Referring to FIG. 12, a pixel PX may be disposed on a base substrate BS, and may include a transistor TR and a light-emitting element OLED. The transistors TR and the light-emitting elements OLED of the pixels PX may be connected to the data lines DL1 to DLn and the first and second power lines PLL1 and PLL2 which are described above.

The transistors TR and the light-emitting elements OLED of the pixels PX may be connected to the pads PD in FIG. 11 through the data lines DL1 to DLn (refer to FIG. 11) and the first and second power lines PLL1 and PLL2 (refer to FIG. 11).

The light-emitting element OLED may include a first electrode AE, a second electrode CE, a hole control layer HCL, an electron control layer ECL, and a light-emitting layer EML. The first electrode AE may be an anode electrode, and the second electrode CE may be a cathode electrode.

The transistor TR and the light-emitting element OLED may be disposed on the base substrate BS. One transistor TR is illustrated, but the pixel PX may substantially include a plurality of transistors and at least one capacitor for driving the light-emitting element OLED.

A display portion DA may include a light-emitting portion PA corresponding to the pixel PX and a non-light-emitting portion NPA around the light-emitting portion PA. The light-emitting element OLED may be disposed in the light-emitting portion PA.

The base substrate BS may include a flexible plastic substrate. In an embodiment, the base substrate BS may include transparent polyimide (“PI”), for example. A buffer layer BFL may be disposed on the base substrate BS, and the buffer layer BFL may be an inorganic layer.

A semiconductor pattern may be disposed on the buffer layer BFL. The semiconductor pattern may include polysilicon. However, the disclosure is not limited thereto, and the semiconductor pattern may include amorphous silicon or metal oxide.

The semiconductor pattern may be doped with an N-type dopant or a P-type dopant. The semiconductor pattern may include a heavily doped region and a lightly doped region. The heavily doped region may have a higher conductivity than the lightly doped region, and may substantially serve as a source electrode and a drain electrode of the transistor TR. The lightly doped region may substantially correspond to an active (or channel) of the transistor.

A source S, an active A, and a drain D of the transistor TR may be formed from the semiconductor pattern. A first insulation layer INS1 may be disposed on the semiconductor pattern. A gate G of the transistor TR may be disposed on the first insulation layer INS1. A second insulation layer INS2 may be disposed on the gate G. A third insulation layer INS3 may be disposed on the second insulation layer INS2.

A connection electrode CNE may be disposed between the transistor TR and the light-emitting element OLED to connect the transistor TR and the light-emitting element OLED. The connection electrode CNE may include a first connection electrode CNE1 and a second connection electrode CNE2.

The first connection electrode CNE1 may be disposed on the third insulation layer INS3 to be connected to the drain D through a first contact hole CH1 defined in the first to third insulation layers INS1 to INS3. A fourth insulation layer INS4 may be disposed on the first connection electrode CNE1. A fifth insulation layer INS5 may be disposed on the fourth insulation layer INS4.

The second connection electrode CNE2 may be disposed on the fifth insulation layer INS5. The second connection electrode CNE2 may be connected to the first connection electrode CNE1 through a second contact hole CH2 defined in the fifth insulation layer INS5. A sixth insulation layer INS6 may be disposed on the second connection electrode CNE2. The first to sixth insulation layers INS1 to INS6 may be inorganic layers or organic layers.

The first electrode AE may be disposed on the sixth insulation layer INS6. The first electrode AE may be connected to the second connection electrode CNE2 through a third contact hole CH3 defined in the sixth insulation layer INS6. A pixel-defining film PDL which exposes a portion of the first electrode AE may be disposed on the first electrode AE and the sixth insulation layer INS6. An opening PX_OP for exposing a portion of the first electrode AE may be defined in the pixel-defining film PDL.

The hole control layer HCL may be disposed on the first electrode AE and the pixel-defining film PDL. The hole control layer HCL may be disposed in the light-emitting portion PA and the non-light-emitting portion NPA in common. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate any one light among red color light, green color light, and blue color light.

The electron control layer ECL may be disposed on the light-emitting layer EML and the hole control layer HCL. The electron control layer ECL may be disposed in the light-emitting portion PA and the non-light-emitting portion NPA in common. The electron control layer ECL may include an electron transport layer and an electron injection layer.

The second electrode CE may be disposed on the electron control layer ECL. The second electrode CE may be disposed in the pixels PX in common. The layers from the buffer layer BFL to the light-emitting element OLED may be defined as a pixel layer PXL.

A thin-film encapsulation layer TFE may be disposed on the light-emitting element OLED. The thin-film encapsulation layer TFE may be disposed on the second electrode CE to cover the pixel PX. The thin-film encapsulation layer TFE may include at least two inorganic layers and an organic layer between the inorganic layers. The inorganic layer may protect the pixel PX from moisture/oxygen. The organic layer may protect the pixel PX from foreign matters such as dust particles.

A first voltage may be applied to the first electrode AE through the transistor TR, and a second voltage having a lower level than the first voltage may be applied to the second electrode CE. Holes and electrons injected into the light-emitting layer EML combine to form excitons, and when the excitons transition to a ground state, the light-emitting element OLED may emit light.

FIG. 13 illustrates a deposition process illustrated in FIGS. 7A to 7D.

Referring to FIGS. 11 to 13, the layers from the base substrate BS to the layer where the hole control layer HCL is disposed may be defined as the substrate SUB. As mentioned above, the transistor TR may be connected to the pads PD through the data lines DL1 to DLn. That is, the substrate SUB may include the data lines DL1 to DLn defined as the aforementioned wirings and the pads PD connected to the data lines DL1 to DLn.

A mask MK may be disposed so as to face the substrate SUB. The mask MK may be disposed next (adjacent) to the substrate SUB. A deposition material EV may be provided onto the substrate SUB through a mask opening OP-MK defined on an upper surface of the mask MK. The light-emitting layer EML may be formed on the substrate SUB by the deposition material EV.

According to the above description, flatness or a degree of sagging of a process target may be measured during a deposition process, and when certain criteria are not fulfilled, flatness or sagging may be improved during the process, thereby improving reliability of the process.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. A deposition apparatus comprising:
a first support part;
a mask frame which is disposed on the first support part, and in which a frame opening is defined;
a mask which is disposed on an upper surface of the mask frame, and in which a mask opening is defined;
an electrostatic chuck which is disposed on the mask, and under which a substrate is disposed;
a second support part, which is disposed on the first support part, with a first support opening defined in an upper surface and a second support opening defined in a lower surface;
a (1-1)-th stage disposed in the first support opening, and configured to rotate about a rotation axis perpendicular to a plane;
a (1-2)-th stage which is disposed on the (1-1)-th stage, and in which a plurality of first openings are defined;
a (2-1)-th stage disposed in the second support opening, and configured to rotate about the rotation axis perpendicular to the plane;
a (2-2)-th stage which is disposed on the (2-1)-th stage, and in which a plurality of second openings are defined; and
a plurality of sensors respectively disposed in the plurality of first openings and the plurality of second openings,
wherein the second support part is movable in a first direction.

2. The deposition apparatus of claim 1, wherein in a plan view, the (1-2)-th stage and the (2-2)-th stage have a circular shape.

3. The deposition apparatus of claim 1, further comprising:
a third support part in which a third support opening is defined; and
a fourth support part which is disposed on the first support part, and in which a fourth support opening is defined.

4. The deposition apparatus of claim 3, wherein the third support part is disposed on the first support part, and
the mask and the first support part are disposed between the third support part and the fourth support part.

5. The deposition apparatus of claim 4, further comprising:
a (3-1)-th stage disposed in the third support opening, and configured to rotate about the rotation axis perpendicular to the plane; and
a (3-2)-th stage which is disposed on the (3-1)-th stage, and in which a plurality of third openings are defined.

6. The deposition apparatus of claim 5, further comprising the plurality of sensors respectively disposed in the plurality of third openings,
wherein the (3-2)-th stage has a circular shape in a plan view.

7. The deposition apparatus of claim 4, further comprising:
a (4-1)-th stage disposed in the fourth support opening, and configured to rotate about the rotation axis perpendicular to the plane; and
a (4-2)-th stage which is disposed on the (4-1)-th stage, and in which a plurality of fourth openings are defined.

8. The deposition apparatus of claim 7, further comprising the plurality of sensors respectively disposed in the plurality of fourth openings,
wherein the (4-2)-th stage has a circular shape in a plan view.

9. The deposition apparatus of claim 3, further comprising a vacuum chamber where a transparent glass substrate is disposed,
wherein the third support part is disposed outside the vacuum chamber, and
the fourth support part is disposed inside the vacuum chamber.

10. The deposition apparatus of claim 9, further comprising:
a (3-1)-th stage disposed in the third support opening, and configured to rotate about the rotation axis perpendicular to the plane;
a (3-2)-th stage which is disposed on the (3-1)-th stage, and in which a plurality of third openings are defined; and
the plurality of sensors respectively disposed in the plurality of third openings.

11. The deposition apparatus of claim 9, further comprising:
a (4-1)-th stage disposed in the fourth support opening, and configured to rotate about the rotation axis perpendicular to the plane;
a (4-2)-th stage which is disposed on the (4-1)-th stage, and in which a plurality of fourth openings are defined; and
the plurality of sensors respectively disposed in the plurality of fourth openings.

12. The deposition apparatus of claim 1, further comprising:
a deposition source disposed under the mask; and
a shutter disposed on the deposition source.

13. A thin-film deposition method comprising:
disposing, on a first support part, a mask frame in which a frame opening is defined;
disposing a mask on an upper surface of the mask frame;
disposing an electrostatic chuck on the mask;
disposing, on the first support part, a second support part with a first support opening defined in an upper surface and a second support opening defined in a lower surface;
disposing, in the first support opening, a (1-1)-th stage configured to rotate about a rotation axis perpendicular to a plane;
disposing, on the (1-1)-th stage, a (1-2)-th stage in which a plurality of first openings are defined;
disposing, in the second support opening, a (2-1)-th stage configured to rotate about the rotation axis perpendicular to the plane;
disposing, on the (2-1)-th stage, a (2-2)-th stage in which a plurality of second openings are defined;
disposing a plurality of sensors respectively in the plurality of first openings and the plurality of second openings;
moving the second support part in a first direction;
measuring a flatness of the electrostatic chuck and a degree of sagging of the mask;
moving the electrostatic chuck in a third direction crossing both the first direction and a second direction crossing the first direction;
disposing a substrate on a lower surface of the electrostatic chuck;
measuring a flatness of the substrate;
moving the second support part in a direction opposite to the first direction; and
depositing a deposition material on the substrate.

14. The thin-film deposition method of claim 13, further comprising:
disposing, on the first support part, a third support part in which a third support opening is defined; and
disposing, on the first support part, a fourth support part in which a fourth support opening is defined,
wherein the mask and the first support part are disposed between the third support part and the fourth support part.

15. The thin-film deposition method of claim 14, further comprising:
disposing, in the third support opening, a (3-1)-th stage configured to rotate about the rotation axis perpendicular to the plane;
disposing, on the (3-1)-th stage, a (3-2)-th stage in which a plurality of third openings are defined; and
disposing the plurality of sensors respectively in the plurality of third openings.

16. The thin-film deposition method of claim 14, further comprising:
disposing, in the fourth support opening, a (4-1)-th stage configured to rotate about the rotation axis perpendicular to the plane;
disposing, on the (4-1)-th stage, a (4-2)-th stage in which a plurality of fourth openings are defined; and
disposing the plurality of sensors respectively in the plurality of fourth openings.

17. The thin-film deposition method of claim 13, further comprising:
disposing a vacuum chamber which includes a transparent glass substrate, and in which the mask, the first support part, and the electrostatic chuck are disposed;
disposing, outside the vacuum chamber, a third support part in which a third support opening is defined; and
disposing, inside the vacuum chamber and on the first support part, a fourth support part in which a fourth support opening is defined.

18. The thin-film deposition method of claim 17, further comprising:
disposing, in the third support opening, a (3-1)-the stage configured to rotate about the rotation axis perpendicular to the plane;
disposing, on the (3-1)-th stage, a (3-2)-th stage in which a plurality of third openings are defined;
disposing, in the fourth support opening, a (4-1)-th stage configured to rotate about the rotation axis perpendicular to the plane;
disposing, on the (4-1)-th stage, a (4-2)-th stage in which a plurality of fourth openings are defined; and
disposing the plurality of sensors respectively in the plurality of third openings and the plurality of fourth openings.

19. The thin-film deposition method of claim 13, further comprising:
inspecting the flatness of the electrostatic chuck;
inspecting the degree of sagging of the mask; and
inspecting the flatness of the substrate.

20. An electronic apparatus comprising:
a display device configured to display an image; and
a processor configured to process an image signal and provide the image signal to the display device,
the display device including: a substrate manufactured by:
disposing, on a first support part, a mask frame in which a frame opening is defined,
disposing a mask on an upper surface of the mask frame,
disposing an electrostatic chuck on the mask,
disposing, on the first support part, a second support part with a first support opening defined in an upper surface and a second support opening defined in a lower surface,
disposing, in the first support opening, a (1-1)-th stage configured to rotate about a rotation axis perpendicular to a plane,
disposing, on the (1-1)-th stage, a (1-2)-th stage in which a plurality of first openings are defined,
disposing, in the second support opening, a (2-1)-th stage configured to rotate about the rotation axis perpendicular to the plane,
disposing, on the (2-1)-th stage, a (2-2)-th stage in which a plurality of second openings are defined,
disposing a plurality of sensors respectively in the plurality of first openings and the plurality of second openings,
moving the second support part in a first direction,
measuring a flatness of the electrostatic chuck and a degree of sagging of the mask,
moving the electrostatic chuck in a third direction crossing both the first direction and a second direction crossing the first direction,
disposing the substrate on a lower surface of the electrostatic chuck,
measuring a flatness of the substrate,
moving the second support part in a direction opposite to the first direction, and
depositing a compound on the substrate.
